(19) United States
(12) Patent Application Publication
(10) Pub. No.: US 2024/0055524 A1
(43) Pub. Date: Feb. 15, 2024

(54) FINFETS WITH REDUCED PARASITICS

(71) Applicant: Micron Technology, Inc., Boise, ID (US)

(72) Inventor: Wenjun Li, Meridian, ID (US)

(21) Appl. No.: 17/883,919

(22) Filed: Aug. 9, 2022

(51) Int. Cl. H01L 29/78; H01L 29/08; H01L 29/66; H01L 27/108; H01L 27/088; H01L 21/8234

(52) U.S. Cl. CPC H01L 29/7851; H01L 29/0847; H01L 29/66795; H01L 27/10826; H01L 27/0886; H01L 21/823431; H01L 21/823418; H01L 2029/7858

(57) ABSTRACT

A variety of applications can include apparatus having a fin field-effect transistor with a gate wrapping around fins to maintain good channel control and planar source and drain regions to reduce Miller capacitance and contact resistance. The reduced parasitic capacitance and resistance can be translated into higher performance and lower power. A fin field-effect transistor can include a bulk semiconductor region having a planar source region structured as a first top portion of the bulk semiconductor region and a planar drain region structured as a second top portion of the bulk semiconductor region, with one or more semiconductor fins contacting the planar source region and the planar drain region with a gate wrapped around the one or more semiconductor fins.

### FIELD OF THE DISCLOSURE

Embodiments of the disclosure relate generally to electronic systems, and more specifically, to fin field-effect transistor devices and formation thereof.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others. Properties of memory devices and other electronic devices can be improved by enhancements to the design and fabrication of components of the electronic devices such as fin field-effect transistors (FinFETs).

### BRIEF DESCRIPTION OF THE DRAWINGS

The drawings, which are not necessarily drawn to scale, illustrate generally, by way of example, but not by way of limitation, various embodiments discussed in the present document.

FIGS. 1A and 1B illustrate top views of fin field-effect transistor architectures that illustrate differences between a fin field-effect transistor structure having Miller capacitance issues with a fin field-effect transistor structure with the Miller capacitance issues mitigated, according to various embodiments.

FIGS. 2A-2F illustrate example components of two architectures of a p-type fin field-effect transistor similar to the architectures of fin field-effect transistor structures of FIGS. 1A and 1B, according to various embodiments.

FIGS. 3A-3C illustrate example components of an architecture of a p-type fin field-effect transistor, according to various embodiments.

FIGS. 4A-4C illustrates example components of an architecture of a n-type fin field-effect transistor, according to various embodiments.

FIG. 5A illustrates a cross-sectional view of example components of a p-type fin field-effect transistor structure along a fin of the p-type fin field-effect transistor structure after formation of source/drain regions, according to various embodiments.

FIG. 5B illustrates a cross-sectional view of example components of a p-type fin field-effect transistor structure after further processing of the p-type fin field-effect transistor structure of FIG. 5A, according to various embodiments.

FIG. 6 illustrates a three-dimensional view of components of a fin field-effect transistor having planar source and drain regions, according to various embodiments.

FIG. 7 illustrates a three-dimensional view of components of the fin field-effect transistor of FIG. 6 with a gate wrapped around semiconductor fins, according to various embodiments.

FIG. 8 illustrates a three-dimensional view of additional components of the fin field-effect transistor of FIGS. 6 and 7, according to various embodiments.

FIG. 9 illustrates a cross-sectional representation of an example fin that can be used as a fin for the fin field-effect transistor of FIGS. 6-8, according to various embodiments.

FIGS. 10A-10H illustrates a process flow of an example method of forming a fin field-effect transistor having planar source/drain regions that can be used with multiple fins, according to various embodiments.

FIG. 11 is a schematic of an example dynamic random-access memory device that can include an architecture having a memory array region and a periphery to the memory array that can include one or more fin field-effect transistors having planar source/drain regions, according to various embodiments.

FIG. 12 is a flow diagram of example features of a method of forming a device including a fin field-effect transistor, according to various embodiments.

FIG. 13 is a block diagram illustrating an example of a machine that be implemented with devices having one or more fin field-effect transistors, according to various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

A 3D structure for FinFETs can include gate wrapping around fins to provide superior channel control relative to planar metal-oxide-semiconductor field-effect transistors (MOSFETs). In various embodimets, the gate wrapping can include portions of the gate being below the fins. In DRAM products, FinFETs can allow shorter gate length and higher speed. However, FinFETs can also suffer from higher parasitic Miller capacitance, which can occur from inner fringing capacitance between gate and fin. FinFETs can also suffer from resistance issues, for example from smaller contact area of conventional FinFETs. This higher parasitic capacitance and higher resistance is detrimental for performance and power, especially in high-scaled pitch cells such as sense amplifiers in memory devices.

In various embodiments, a FinFET can be structured with gate wrapping around fins to maintain good channel control and structured with planar source and drain to reduce Miller capacitance and contact resistance. The gate wrapping can include portions of the gate being below the fins. The reduced parasitic capacitance and lower contact resistance can be translated into higher performance and lower power. Fabrication steps can be reduced with at least skipping one epitaxial process. A planar semiconductor structure is a structure formed on a plane of a substrate, for example, planar source/drain regions are formed on a same side of a common substrate such as a bulk semiconductor. A bulk semiconductor is a piece of semiconductor material having characteristics with uniform properties throughout the whole piece, as measured in those parts of the piece in which the measured value of a characteristic is not modified by the proximity to the boundaries of the piece.

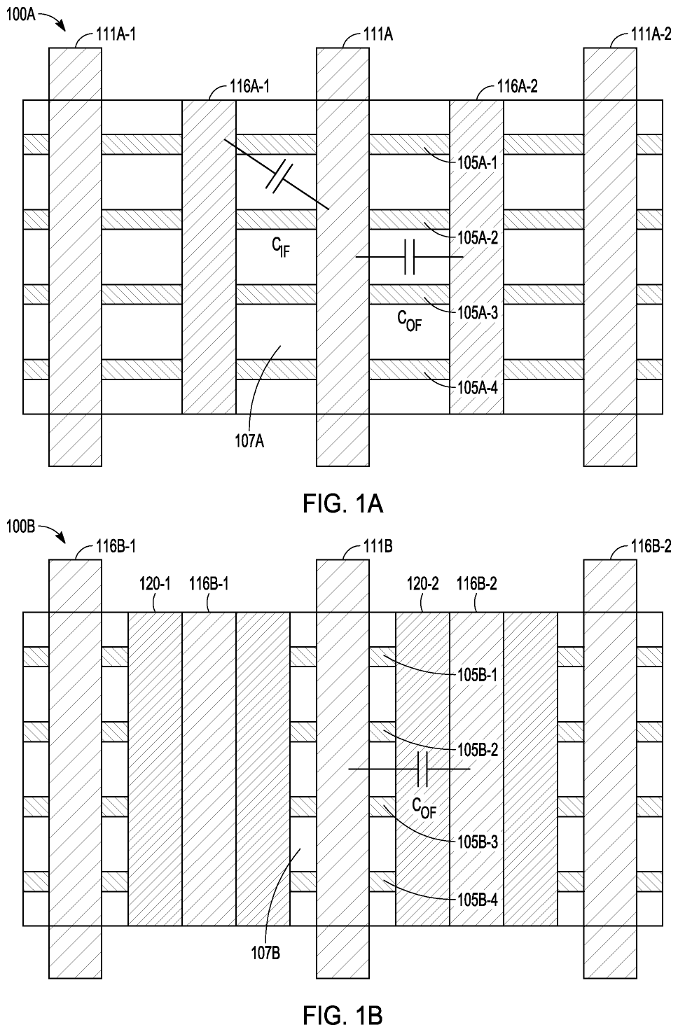

FIGS. 1A and 1B illustrate top views of FinFET architectures that illustrate differences between a FinFET structure 100A having a Miller capacitance issue with a FinFET structure 100B with the Miller capacitance issues of FinFET structure 100A mitigated. FIG. 1A shows FinFET structure 100A having a gate structure 111A around fins 105A-1, 105A-2, 105A-3, and 105A-4, where these fins are under gate structure 111A and are separated by a dielectric 107A. Though four fins are shown in FIG. 1A, such a FinFET structure 100A can have more or less than four fins. Each of fins 105A-1, 105A-2, 105A-3, and 105A-4 connect to a source/drain region on each side of gate structure 111A, where the source/drain regions are under contacts 116A-1 and 116A-2. For the four fin architecture, there are four source/drain regions that are connected together, resulting in a number of edges for these regions. An inner fringing capacitance C_{if} can occur between gate structure 111A and fin 105A-1 and associated epitaxial source/drain region under source/drain contact 116A-1, which is a unique Miller component for a FinFET. A C_{if} can occur for each of fins 105A-1, 105A-2, 105A-3, and 105A-4. An outer fringing capacitance C_{of} occurs between gate structure 111A and contact 116A-2, and a C_{of} occurs between gate structure 111A and contact 116A-1. FinFET structure 100A includes gate structures 111A-1 and 111A-2 that are dummy gate structures can be used to ensure uniform gate pitch and reduce process variation in the integrated circuit in which FinFETs are being formed.

FIG. 1B illustrates an embodiment of an example FinFET structure 100B having a gate structure 111B and dummy gate structures 111B-1 and 111B-2 with source/drain regions 120-1 and 120-2 on each side of gate structure 111B. Four fins 105B-1, 105B-2, 105B-3, and 105B-4 can be structured under gate structure 111B with gate structure 111B around fins 105B-1, 105B-2, 105B-3, and 105B-4, where the fins can have a reduced length and are separated by a dielectric 107B. Though four fins are shown in FIG. 1B, such a FinFET structure 100B can have more or less than four fins. Source/drain regions 120-1 and 120-2 can be formed with a continuous, uniform structure, which can significantly reduce edges associated with FinFET structure 100A. The continuous, uniform structure of source/drain regions 120-1 and 120-2 provides a planar structure. With FinFET structure 100B, fins 105B-1, 105B-2, 105B-3, and 105B-4 can be connected to source/drain regions 120-1 and 120-2, where source/drain region 120-1 has a contact 116B-1 and a source/drain region 120-2 has a contact 116B-2. With source/drain regions 120-1 and 120-2 structured as continuous, uniform structures, the number of edges, resulting from multiple source/drain regions associated with FinFET structure 100A, is reduced such that an inner fringing capacitance C_{if} is effectively removed in FinFET structure 100B. An C_{of} between gate structure 111B and contact 116B-2 and a C_{of} between gate structure 111B and contact 116B-1 can occur similar to FinFET structure 100A of FIG. 1A. FinFET structure 100B provides gate wrapping around fins, which can maintain good channel control, and, relative to FinFET structure 100A, provides a planar source and drain, which can mitigate and significantly Miller capacitance and contact resistance. The reduced parasitic capacitance and resistance can be translated into higher performance and lower power.

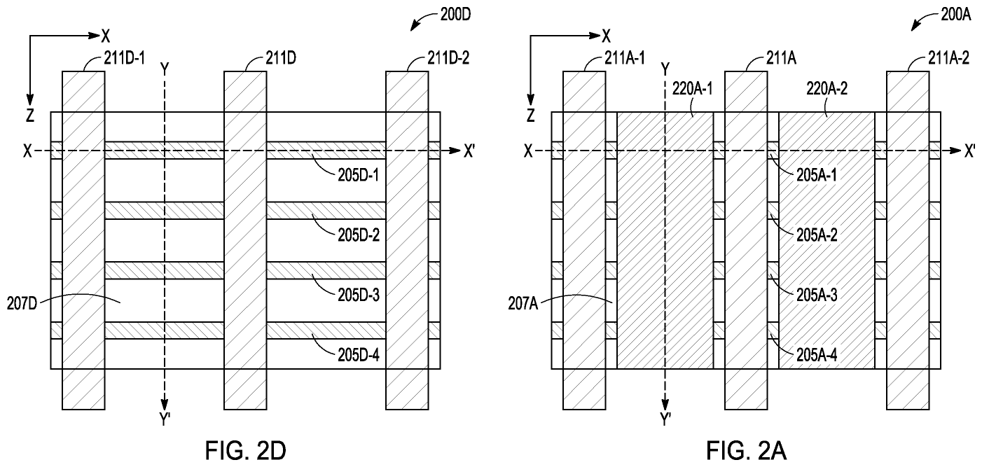

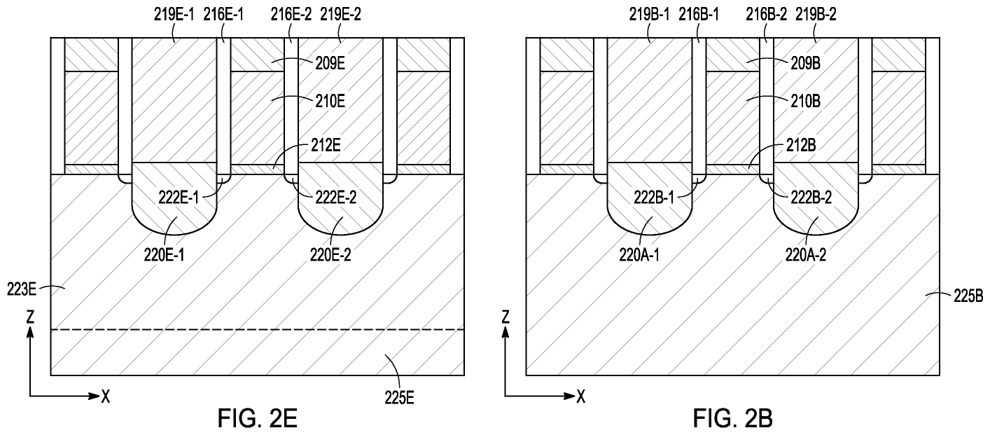

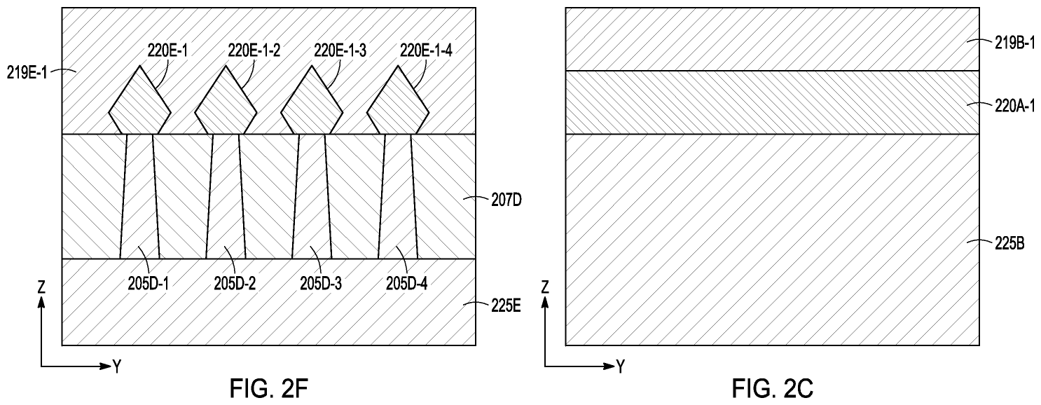

FIGS. 2A-2F illustrate an embodiment of example components of an architecture 200A of a p-type FinFET, similar to FinFET structure 100B, and components of an architecture 200D of a p-type FinFET, similar to FinFET structure 100A. FIG. 2A shows a top view of components of architecture 200A having planar source/drain regions 220A-1 and 220A-2. Planar source/drain regions 220A-1 and 220A-2 are connected by fins 205A-1, 205A-2, 205A-3, and 205A-4. A gate structure 211A wraps fins 205A-1, 205A-2, 205A-3, and 205A-4 with a dielectric 207A providing electrical insulation between fins 205A-1, 205A-2, 205A-3, and 205A-4 and between gate structure 211A and source/drain regions 220A-1 and 220A-2. Architecture 200A includes gate structures 211A-1 and 211A-2 that are dummy gate structures. Formation of gate structures 211A-1 and 211A-2 can follow the same process as formation of gate structure 211A and have the same materials as gate structure 211A. The same materials can include gate dielectrics in gate structures 211A-1 and 211A-2 being identical to the gate dielectric in gate structure 211A. The dummy gates, gate structures 211A-1 and 211A-2, can be used to ensure uniform gate pitch and reduce process variation in the integrated circuit in which FinFETs are being formed.

FIG. 2D illustrates a top view of an embodiment of example components of architecture 200D having source/drain regions contacting fins 205D-1, 205D-2, 205D-3, and 205D-4, where the source/drain regions can be at the intersection of line X-X′ and line Y-Y′. A gate structure 211D wraps fins 205D-1, 205D-2, 205D-3, and 205D-4 with a dielectric 207D providing electrical insulation between fins 205D-1, 205D-2, 205D-3, and 205D-4 and between gate structure 211D and source/drain regions. Architecture 200D includes gate structures 211D-1 and 211D-2 that are dummy gate structures.

FIGS. 2A and 2D, similar to FIGS. 1A and 1B, illustrate performance enhancements provided by architecture 200A over architecture 200D. The relationship of gate structure 211A and fins 205A-1, 205A-2, 205A-3, and 205A-4 of FIG. 2A can be viewed with respect to the relationship of gate structure 211D and fins 205D-1, 205D-2, 205D-3, and 205D-4. Associated epitaxial source/drain regions can be viewed along line X-X′ and line Y-Y′. Source/drain regions 220A-1 and 220A-2 provide a continuous, uniform structure, significantly reducing edges associated with architecture 200D.

FIG. 2B illustrates a cross-sectional view of an embodiment of example components of architecture 200A along line X-X′ of FIG. 2A. Line X-X′ is along fin 205A-1. For ease of discussion, components of dummy gate structures 211A-1 and 211A-2 are not labelled in FIGS. 2A and 2B. Gate structure 211A of FIG. 2A can include a top portion 209B on a gate 210B on a gate dielectric 212B. Top portion 209B can be, but is not limited to, a dielectric nitride. Gate 210B can be, but is not limited to, a polysilicon gate. Gate dielectric 212B can be, but is not limited to, a gate oxide. The gate oxide can be, but is not limited to, silicon oxide. Spacers 216B-1 and 216B-2 can be located along top portion 209B, gate 210B, and gate dielectric 212B of gate structure 211A. Spacers 216B-1 and 216B-2 can be one or more dielectric regions, which can include a dielectric nitride and a dielectric oxide. Source/drain regions 220A-1 and 220A-2 can be located in bulk substrate 225B on opposite sides of gate 210B. Source/drain regions 220A-1 and 220A-2 can be silicon germanium (SiGe) epitaxial regions grown on bulk substrate 225B. SiGe epitaxial regions, used for source/drain regions 220A-1 and 220A-2, provide enhanced hole mobility and reduced resistance of source/drain regions 220A-1 and 220A-2. Regions 222B-1 and 222B-2 can be p+ implant regions effectively under spacers 216B-1 and 216B-2. Dielectric fillers 219B-1 and 219B-2 can be located above source/drain regions 220A-1 and 220A-2.

FIG. 2E illustrates a cross-sectional view of an embodiment of example components of architecture 200D along line X-X′ of FIG. 2D. Line X-X′ is along fin 205D-1 of FIG. 2D. For ease of discussion, components of dummy gate structures 211D-1 and 211D-2 are not labelled in FIGS. 2D and 2E. As shown in FIG. 2E, gate structure 211D of FIG. 2D can include a top portion 209E on a gate 210E on a gate dielectric 212E. Top portion 209E can be, but is not limited to, a dielectric nitride. Gate 210E can be, but is not limited to, a polysilicon gate. Gate dielectric 212E can be, but is not limited to, a gate oxide. The gate oxide can be, but is not limited to, silicon oxide. Spacers 216E-1 and 216E-2 can be located along top portion 209E, gate 210E, and gate dielectric 212E of gate structure 211D. Spacers 216E-1 and 216E-2 can be one or more dielectric regions, which can include a dielectric nitride and a dielectric oxide. Source/drain regions 220E-1 and 220E-2 can be located on a fin region 223E on opposite sides of gate 210E. Fin region 223E includes the material of fins that extends from a bulk substrate 225E, where the material of fins is that of the bulk substrate 225E. Source/drain regions 220E-1 and 220E-2 can be grown SiGe epitaxial regions. Regions 222E-1 and 222E-2 can be p+ implant regions effectively under spacers 216E-1 and 216E-2. Since FIG. 2B and FIG. 2E are cross-sectional views along line X-X′, the components of architecture 200A and architecture 200D are similar. Dielectric fillers 219E-1 and 219E-2 can be located above source/drain region at intersection of X-X′ and Y-Y′ of architecture 200D.

FIG. 2C illustrates a cross-sectional view of an embodiment of example components of architecture 200A along line Y-Y′ of FIG. 2A. Line Y-Y′ is along a direction perpendicular to fins 205A-1, 205A-2, 205A-3, and 205A-4. FIG. 2C shows source/drain region 220A-1 formed on bulk substrate 225B. Source/drain region 220A-1 is structured as one continuous, uniform uniform region, which can be formed by epitaxy growth. Dielectric filler 219B-1 is located on source/drain regions 220A-1.

FIG. 2F illustrates a cross-sectional view of an embodiment of example components of architecture 200D along line Y-Y′ of FIG. 2D. Line Y-Y′ is along a direction perpendicular to fins 205D-1, 205D-2, 205D-3, and 205D-4. FIG. 2F shows source/drain regions 220E-1, 220E-1-2, 220E-1-3, and 220E-1-4 on fins 205D-1, 205D-2, 205D-3, and 205D-4, respectively. Fins 205D-1, 205D-2, 205D-3, and 205D-4 are formed extending vertically from bulk substrate 225E. Since FIG. 2E is a cross-sectional view along X-X′ of FIG. 2D, which is along fin 205D-1, fin region 223E in FIG. 2E represents material of fin 205D-1. Fins 205D-1, 205D-2, 205D-3, and 205D-4 are separated from each other by dielectric 207D. Source/drain regions 220E-1, 220E-1-2, 220E-1-3, and 220E-1-4 can be formed as individual regions that are contacted together. Source/drain regions 220E-1, 220E-1-2, 220E-1-3, and 220E-1-4 can be formed with shapes that overlap to form a single source/drain with multiple edges. The shapes of source/drain regions 220E-1, 220E-1-2, 220E-1-3, and 220E-1-4 can be diamond-like shapes. Dielectric filler 219E-1 is located on source/drain regions 220E-1, 220E-1-2, 220E-1-3, and 220E-1-4. FIGS. 2C and 2F illustrate the basis for the capacitance properties of architecture 200A relative to architecture 200D.

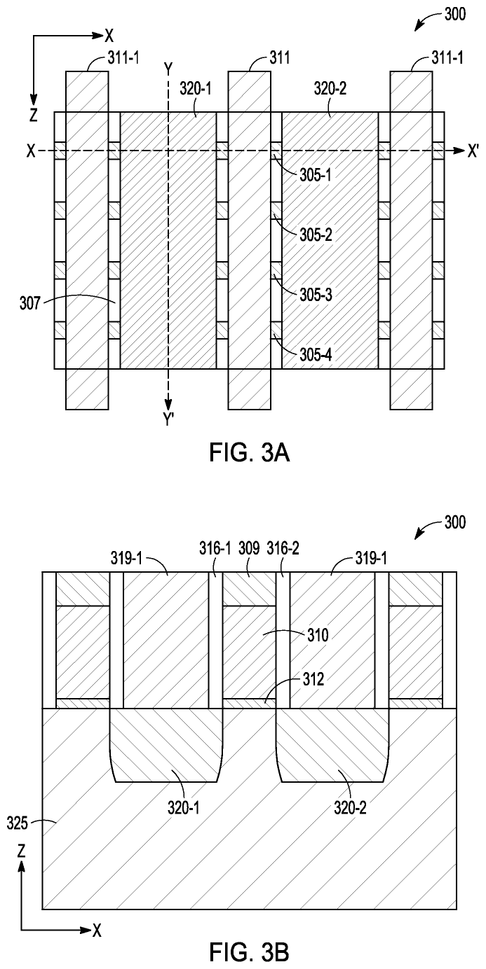

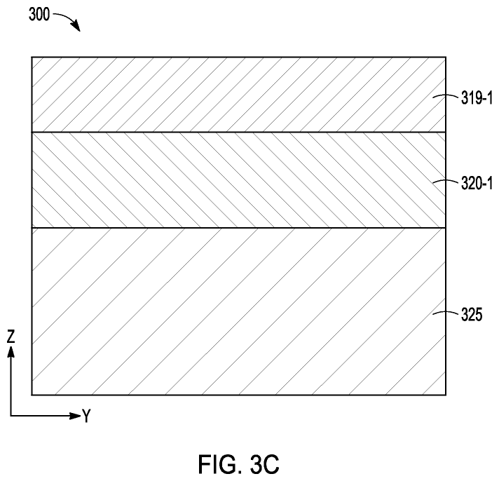

FIGS. 3A-3C illustrates an embodiment of example components of an architecture 300 of a p-type FinFET, similar to FinFET structures 100B and 200A. FIG. 3A shows a top view of components of architecture 300 having planar source/drain regions 320-1 and 320-2. Planar source/drain regions 320-1 and 320-2 are contacted by fins 305-1, 305-2, 305-3, and 305-4. A gate structure 311 wraps fins 305-1, 305-2, 305-3, and 305-4 with a dielectric 307 providing electrical insulation between gate structure 311 and planar source/drain regions 320-1 and 320-2 and between fins 305-1, 305-2, 305-3, and 305-4. Architecture 300 includes gate structures 311-1 and 311-2 that are dummy gate structures.

FIG. 3B illustrates a cross-sectional view of an embodiment of example components of architecture 300 along line X-X′ of FIG. 3A. Line X-X′ is along fin 305A-1. For ease of discussion, components of dummy gate structures 311-1 and 311-2 are not labelled. As shown in FIG. 3B, gate structure 311 of FIG. 3A can include a top portion 309 on a gate 310 on a gate dielectric 312. Top portion 309 can be, but is not limited to, a dielectric nitride. Gate 310 can be, but is not limited to, a polysilicon gate. Gate dielectric 312 can be, but is not limited to, a gate oxide. The gate oxide can be, but is not limited to, silicon oxide. Spacers 316-1 and 316-2 can be located along top portion 309, gate 310, and gate dielectric 312 of gate structure 311. Spacers 316-1 and 316-2 can be one or more dielectric regions, which can include a dielectric nitride and a dielectric oxide. Source/drain regions 320-1 and 320-2 can be located in bulk substrate 325 on opposite sides of gate 310. Source/drain regions 320-1 and 320-2 can be p+ implant regions grown on bulk substrate 325. Source/drain regions 320-1 and 320-2 can be, but are not limited to, silicon regions having p+ implants. Dielectric fillers 319-1 and 319-2 can be located above source/drain regions 320-1 and 320-2. Source/drain regions 320-1 and 320-2, structured as p+ implant regions, can be formed without an epitaxial growth, which can lower the process cost relative to source/drain regions 220A-1 and 220A-2 of architecture 200A of FIGS. 2B and 2C.

FIG. 3C illustrates a cross-sectional view of an embodiment of example components of architecture 300 along line Y-Y′ of FIG. 3A. Line Y-Y′ is along a direction perpendicular to fins 305-1, 305-2, 305-3, and 305-4. For ease of discussion, components of dummy gate structures 311-1 and 311-2 are not labelled. FIG. 3C shows source/drain region 320-1 formed on bulk substrate 325. Source/drain region 320-1 is structured as one continuous, uniform region, which can be formed by p+ implant. Dielectric filler 319-1 is located on source/drain region 320-1.

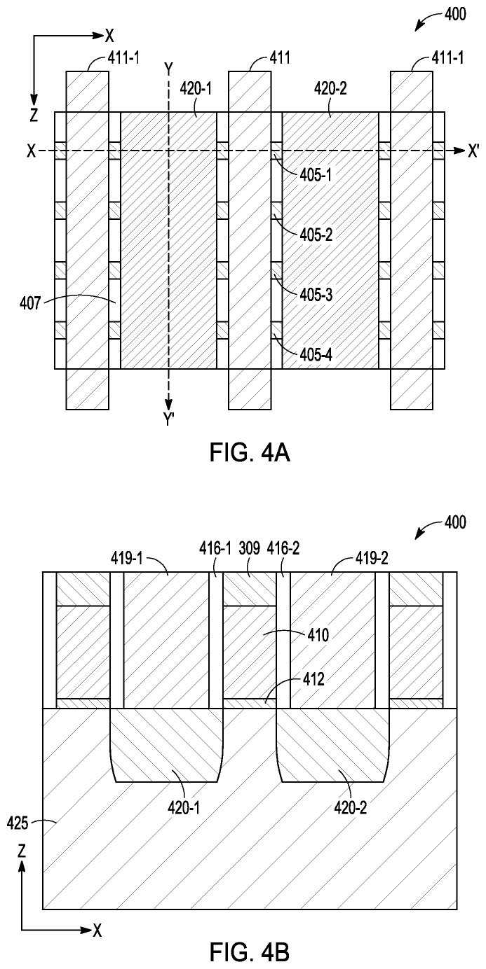

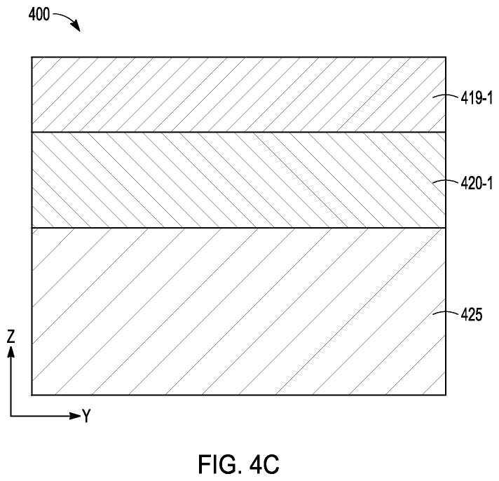

FIGS. 4A-4C illustrates an embodiment of example components of an architecture 400 of a n-type FinFET, similar to FinFET structure 100B. FIG. 4A illustrates a top view of components of architecture 400 having planar source/drain regions 420-1 and 420-2. Planar source/drain regions 420-1 and 420-2 are contacted by fins 405-1, 405-2, 405-3, and 405-4. A gate structure 411 wraps fins 405-1, 405-2, 405-3, and 405-4 with a dielectric 407 providing electrical insulation between gate structure 411 and source/drain regions 420-1 and 420-2 and between fins 405-1, 405-2, 405-3, and 405-4. Architecture 400 includes gate structures 411-1 and 411-2 that are dummy gate structures.

FIG. 4B illustrates a cross-sectional view of an embodiment of example components of architecture 400 along line X-X′ of FIG. 4A. Line X-X′ is along fin 405A-1. For ease of discussion, components of dummy gate structures 411-1 and 411-2 are not labelled. As shown in FIG. 4B, gate structure 411 of FIG. 4A can include a top portion 409 on a gate 410 on a gate dielectric 412. Top portion 409 can be, but is not limited to, a dielectric nitride. Gate 410 can be, but is not limited to, a polysilicon gate. Gate dielectric 412 can be, but is not limited to, a gate oxide. The gate oxide can be, but is not limited to, silicon oxide. Spacers 416-1 and 416-2 can be located along top portion 409, gate 410, and gate dielectric 412 of gate structure 411. Spacers 416-1 and 416-2 can be one or more dielectric regions, which can include a dielectric nitride and a dielectric oxide. Source/drain regions 420-1 and 420-2 can be located in bulk substrate 425 on opposite sides of gate 410. Source/drain regions 420-1 and 420-2 can be formed on bulk substrate 425 with n+ implants. Source/drain regions 420-1 and 420-2 can be, but are not limited to, silicon regions having n+ implants. Dielectric fillers 419-1 and 419-2 can be located above source/drain regions 420-1 and 420-2.

FIG. 4C illustrates a cross-sectional view of an embodiment of example components of architecture 400 along line Y-Y′ of FIG. 4A. Line Y-Y′ is along a direction perpendicular to fins 405-1, 405-2, 405-3, and 405-4. For ease of discussion, components of dummy gate structures 411-1 and 411-2 are not labelled. FIG. 4C shows source/drain region 420-1 formed on bulk substrate 425. Source/drain region 420-1 is structured as one continuous, uniform region. Dielectric filler 419-1 is located on source/drain region 420-1.

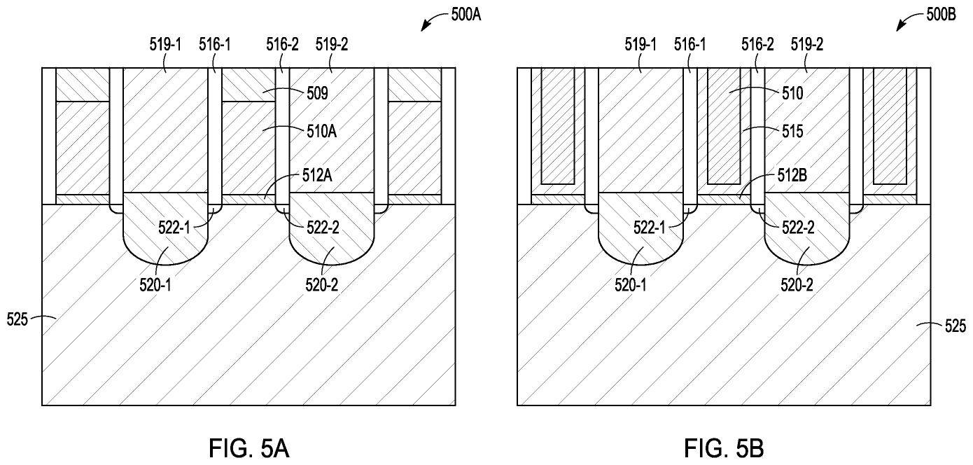

FIG. 5A illustrates a cross-sectional view of an embodiment of example components of a p-type FinFET structure 500A along a fin of p-type FinFET structure 500A after formation of source/drain regions 520-1 and 520-2. Source/drain regions 520-1 and 520-2 can be formed as a regrown epitaxy regions. For example, source/drain regions 520-1 and 520-2 can be formed as SiGe epitaxial regions. P-type FinFET structure 500A also includes a gate structure having a top portion 509 on a gate 510A on a gate dielectric 512A. Top portion 509 can be, but is not limited to, a dielectric nitride. Gate 510A can be, but is not limited to, a polysilicon gate. Gate dielectric 512A can be, but is not limited to, a gate oxide. The gate oxide can be, but is not limited to, silicon oxide. Spacers 516-1 and 516-2 can be located along top portion 509, gate 510A, and gate dielectric 512A. Spacers 516-1 and 516-2 can be one or more dielectric regions, which can include a dielectric nitride and a dielectric oxide. Source/drain regions 520-1 and 520-2 can be located in bulk substrate 525 on opposite sides of gate 510A. Source/drain regions 520-1 and 520-2 can be SiGe epitaxial regions grown on bulk substrate 525. Regions 522-1 and 522-2 can be p+ implant regions effectively under spacers 516-1 and 516-2. Dielectric fillers 519-1 and 519-2 can be located above source/drain regions 520-1 and 520-2.

FIG. 5B illustrates a cross-sectional view of an embodiment of example components of a p-type FinFET structure 500B after further processing p-type FinFET structure 500A of FIG. 5A. Top portion 509, gate 510A, and gate dielectric 512A have been removed. A high-k gate dielectric has been deposited as part of a gate dielectric 512B. A high-k dielectric is a dielectric having a dielectric constant greater than 3.9, which is the dielectric constant of silicon oxide. A low-k dielectric is a dielectric having a dielectric constant lower than 3.9. Gate dielectric 512B can include a silicon oxide region on which the high-k gate dielectric is formed. The high-k gate dielectric can include, but is not limited to, hafnium oxide (HfOₓ). A work function metal 515 has been deposited and a metal 510 has been filled within work function metal 515, followed by planarization. Work function metal 515 can include titanium nitride (TiN), tantalum nitride (TaN), other metals, or multiple metallic regions. Metal 510 can be the primary conductive region and can include, but is not limited to, tungsten (W). Though not shown, a gate contact, a drain contact, and a source contact can be formed to p-type FinFET structure 500B.

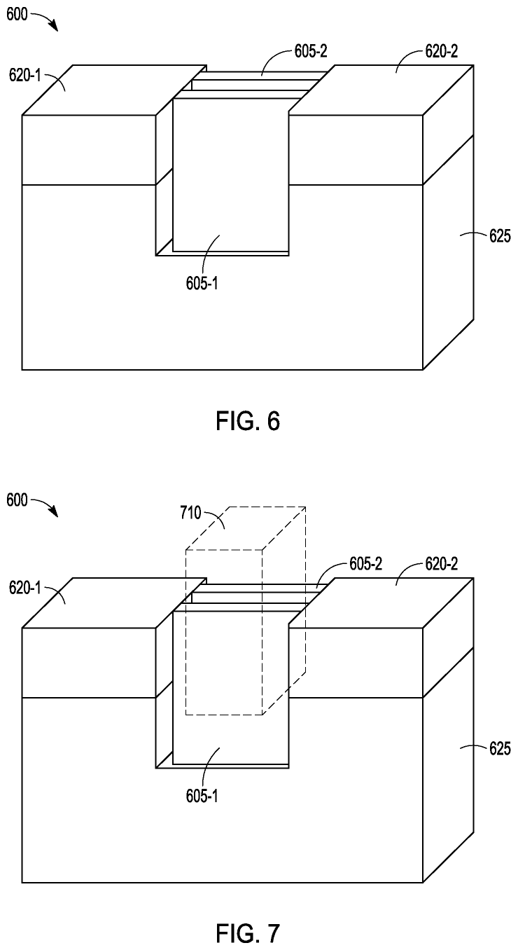

FIG. 6 illustrates a 3D view of an embodiment of example components of a FinFET 600 having planar source and drain regions. FinFET 600 includes a bulk semiconductor region 625 having a recessed region, where bulk semiconductor region 625 can be located on a substrate. A source/drain region 620-1 can be structured as a first top portion of bulk semiconductor region 625, where source/drain region 620-1 is located adjacent to a first side of the recessed region. A source/drain region 620-2 can be structured as a second top portion of the bulk semiconductor region 625, source/drain region 620-2 is located adjacent to a second side of the recessed region. The first side is opposite the second side. Semiconductor fins 605-1 and 605-2 can be located in the recessed region. Semiconductor fin 605-1 contacts source/drain region 620-1 and source/drain region 620-2. Semiconductor fin 605-2 contacts source/drain region 620-1 and source/drain region 620-2. Though two fins are shown in FIG. 6, FinFET 600 can have more or less than two fins in the recessed region of bulk semiconductor region 625. To view the relationship of semiconductor fins 605-1 and 605-2 with respect to the planar structure of source/drain regions 620-1 and 620-2, other components are not shown.

FinFET 600 can be structured as p-type FinFET or a n-type FinFET. As a p-type FinFET, FinFET 600 can be structured in a number of different formats. FinFET 600, as a p-type FinFET, can include source/drain region 620-2 and source/drain region 620-1 being a SiGe epitaxial region. FinFET 600, as a p-type FinFET, can include source/drain region 620-2 and source/drain region 620-1 being a semiconductor region having p+ implants. FinFET 600, as a n-type FinFET, can include source/drain region 620-2 and source/drain region 620-1 being a semiconductor region having n+ implants. Bulk semiconductor region 625 can be, but is not limited to, a bulk silicon region. With bulk semiconductor region 625 being a silicon bulk region, semiconductor fins 605-1 and 605-2 can be silicon fins.

FIG. 7 illustrates a 3D view of an embodiment of example components of FinFET 600 having planar source and drain regions of FIG. 6 with a gate 710 wrapped around semiconductor fins 605-1 and 605-2. Gate 710 can be located at least partially in the recessed region of bulk semiconductor region 625. Gate 710 can be formed around and on top of semiconductor fins 605-1 and 605-2 separated from semiconductor fins 605-1 and 605-2 by a gate dielectric. In various embodimets, the gate wrapping can include portions of the gate being below the fins. Though FIG. 7 shows gate 710 wrapped around two semiconductor fin, gate 710 can be wrapped around more or less than two semiconductor fins. Gate 710 can be structured as, but is not limited to, a metal gate. The metal gate can be structured as one or more metallic regions. The metal gate can include a number of metal regions in which a primary metal is formed. The primary metal can be, but is not limited to, W. The metal regions, in which W can be structured, can include metallic materials such as, but not limited to, TiN, TaN, or other metallic material that provides work function properties for the primary metal. Though source/drain regions 620-1 and 620-2 are shown as rectangular cuboids in FIGS. 6 and 7, other shapes that are continuous and uniform with respect to semiconductor fins 605-1 and 605-2 and gate 710 can be implemented.

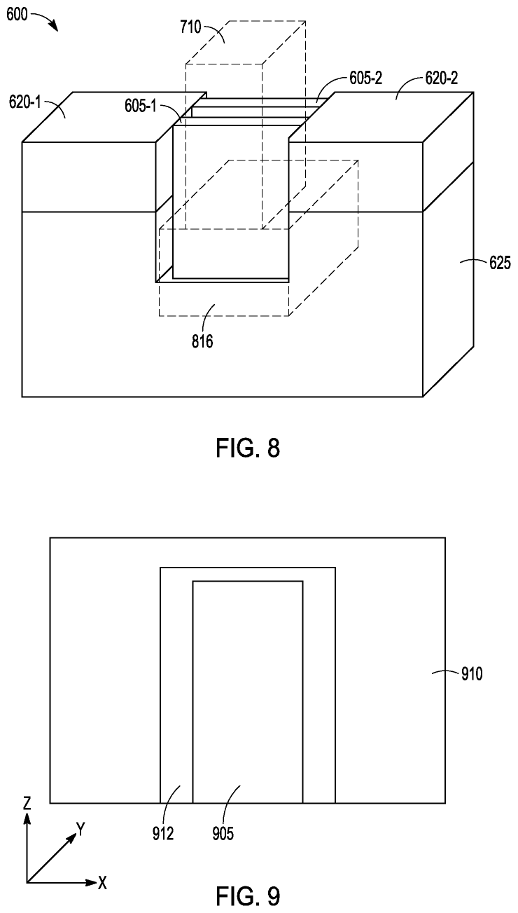

FIG. 8 illustrates a three-dimensional view of additional components of FinFET 600 of FIGS. 6 and 7. A dielectric isolation region 816 provides electrical isolation in the recessed region of bulk semiconductor region 625 between source/drain region 620-1, source/drain region 620-2, gate 710, semiconductor fin 605-1, and semiconductor fin 605-2. Dielectric isolation region 816 can be, but is not limited to, a silicon oxide region. Dielectric isolation region 816 along with the other components of FIGS. 6 and 7 provides a FinFET 600 that can include a planar p+ implant region, a planar n+ implant region, or a planar SiGe epitaxial region on top of a planar region and absence of shallow trench isolation (STI) in source/drain regions 620-1 and 620-2. Although FinFET 600 can have a capacitance between gate 710 and source/drain region 620-1 and between gate 710 and source/drain region 620-1, the planar source/drain regions 620-1 and 620-2 can provide for substantial reduction of fringing capacitance components of gate to source/drain epitaxial bottom or sidewall and gate to source/drain epitaxial side walls associated with FinFETs having source/drain regions located on fins, for example, as shown for example with respect to FIG. 2F.

FIG. 9 illustrates a cross-sectional representation of an embodiment of an example fin 905 that can be used as a fin for FinFET 600 of FIGS. 6-8. A surface of fin 905 is shown in the x-z plane, where fin 905 is arranged in the y-direction and contacts a planar source/drain in a plane parallel to the surface of fin 905. A gate 910 wraps fin 905 and is separated from fin 905 by a gate dielectric 912. Gate 910 can be implemented as gate 710 of FIGS. 7 and 8. Gate 910 and gate dielectric 912 can be implemented as a high-k metal gate (HKMG). A HKMG is a gate comprising a metal located on a high-k dielectric. The high-k dielectric can be located on a thin layer of silicon oxide. The metal of a HKMG can include one or more metallic components providing gate 910 with electrical characteristics of a metal.

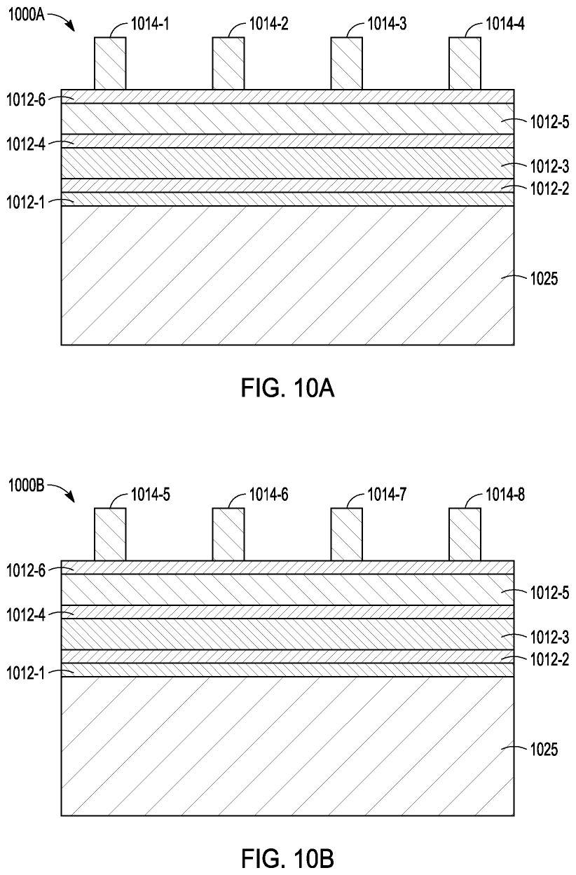

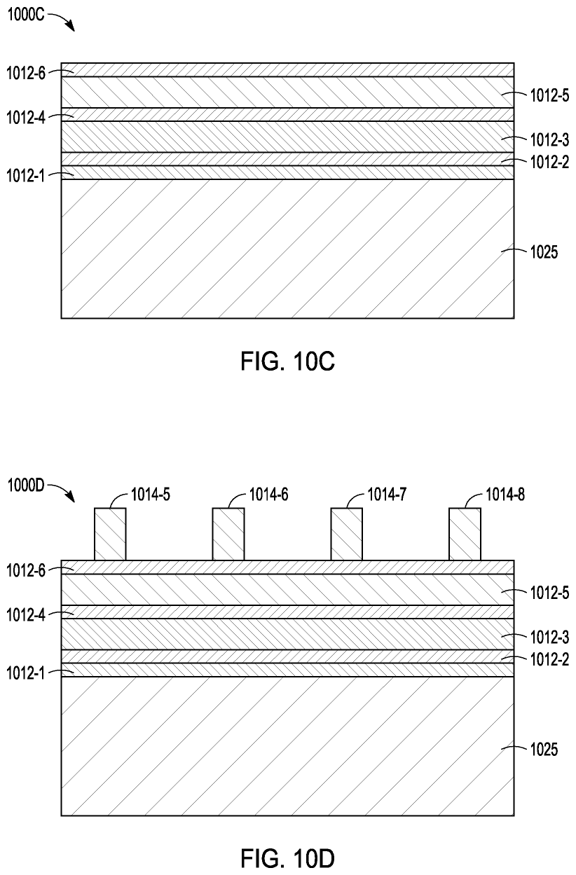

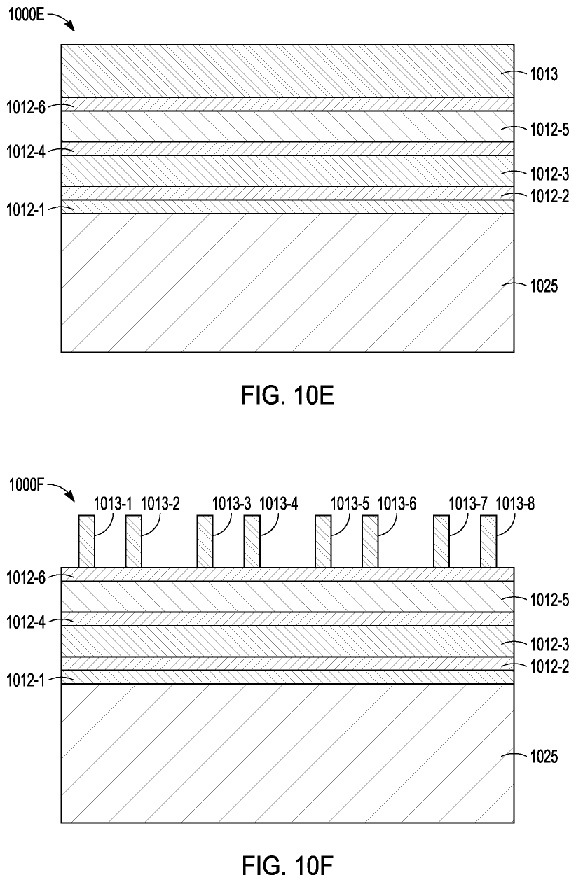

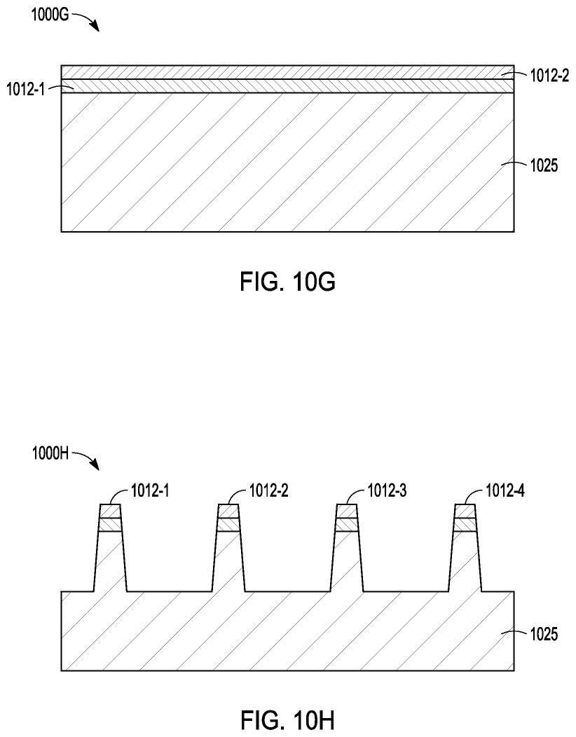

FIGS. 10A-10H is a process flow of an embodiment of an example method of forming a FinFET having planar source/drain regions that can be used with multiple fins. FIGS. 10A, 10C, 10E, and 10G show the process flow in source/drain regions, and FIGS. 10B, 10D, 10F, and 10H show the process flow in gate regions. FIGS. 10A and 10B show structures 1000A and 1000B at a time after regions 1012-1, 1012-2, 1012-3, 1012-4, 1012-5, and 1012-6 have been formed on a bulk semiconductor 1025, which can be a substrate. Bulk semiconductor 1025 can be a silicon region. Several of regions 1012-1, 1012-2, 1012-3, 1012-4, 1012-5, and 1012-6 can function as etch stops in the flow process. Appropriate materials, such as dielectric materials, can be used for these etch stops. For a non-limiting example, regions 1012-1 and 1012-3 can be oxide layers; regions1012-2 and 1012-4 can be nitride layers; region 1012-5 can be a carbon layer; and region 1012-6 can be an oxide region, a nitride region, or a region of a combination of an oxide and a nitride. Fin mandrels 1014-1, 1014-2, 1014-3, 1014-4, 1014-5, 1014-6, 1014-7, and 1014-8 have been patterned and formed using appropriate lithography. Fin mandrels 1014-1, 1014-2, 1014-3, 1014-4, 1014-5, 1014-6, 1014-7, and 1014-8 can be carbon mandrels.

FIGS. 10C and 10D show structures 1000C and 1000D at a second time in the process flow. Lithography has been applied to open source/drain regions in the source/drain regions of structure 1000C and fin mandrels 1014-1, 1014-2, 1014-3, and 1014-4 have been etched off. At the same time, structure region 1000D maintains the arrangement of structure region 1000B.

FIGS. 10E and 10F show structure regions 1000E and 1000F at a third time in the process flow. A spacer 1013 has been deposited in source/drain regions forming structure region 1000E. Spacers 1013-1, 1013-2, 1013-3, 1013-4, 1013-5, 1013-6, 1013-7, and 1013-8 have been deposited in gate regions about fin mandrels 1014-5, 1014-6, 1014-7, and 1014-8 in a pair-wise manner and fin mandrels 1014-5, 1014-6, 1014-7, and 1014-8 have been removed forming structure region 1000F. Fin mandrels 1014-5, 1014-6, 1014-7, and 1014-8 can be removed using an appropriate etch process for the materials used in forming fin mandrels 1014-5, 1014-6, 1014-7, and 1014-8.

FIGS. 10G and 10H show structure regions 1000G and 1000H at a fourth time in the process flow. Spacer deposition 1013 has been used to control etching to form fins in gate regions resulting in structure region 1000H, while etching in source/drain regions results in forming planar source/drain regions in structure region 1000G. Planar source and drain regions are formed by removing the fin stack during the fin chop process.

Various deposition techniques for components of structures 1000A-1000H in the process flow of FIGS. 10A-10H can be used that are typical for the material being formed, the dimensions of the material being formed, and the architecture in which the material is being formed in the fabrication of the memory device. Material and structures can be formed by a suitable process such as, but not limited to, a deposition process including but not limited to physical vapor deposition (PVD), chemical vapor deposition (CVD), atomic layer depositon (ALD), or other deposition process. Other processes can be used. Selective etching can be used to remove selected regions in the processing discussed with respect to FIGS. 10A-10H. Selective etching is a process in which one or more materials are removed from a structure, while one or more other materials remain in the structure with no or little removal. Selective etching can depend on the material to be etched, the material not to be etched, the etchant employed, and the method for etching. Types of etching include wet etching and dry etching, where each of these two basic methods include a number of different etching procedures. In addtion, conventional masking techniques, providing protective regions in the processing, can be used in removal of selected regions in forming the components of the memory device.

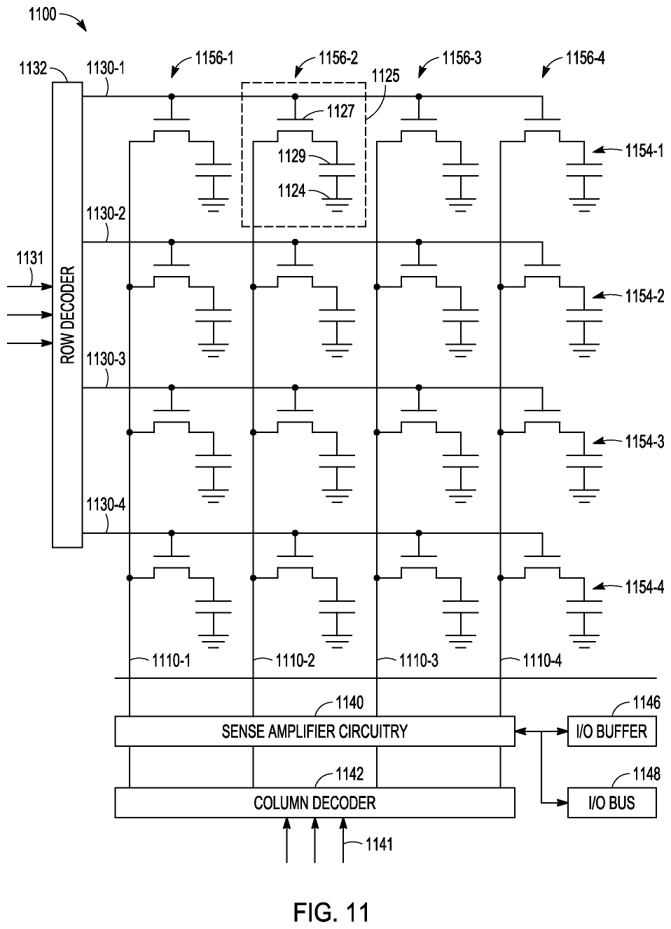

FIG. 11 is a schematic of an embodiment of an example DRAM device 1100 that can include an architecture having a memory array region and a periphery to the memory array that can include one or more FinFETs. DRAM device 1100 includes an array of memory cells 1125 (only one being labeled in FIG. 11 for ease of presentation) arranged in rows 1154-1, 1154-2, 1154-3, and 1154-4 and columns 1156-1, 1156-2, 1156-3, and 1156-4. For simplicity and ease of discussion, the array is shown in only two dimensions, but the array can be extended into the third dimension. Further, while only four rows 1154-1, 1154-2, 1154-3, and 1154-4 and four columns 1156-1, 1156-2, 1156-3, and 1156-4 of four memory cells are illustrated, DRAM devices like DRAM device 1100 can have significantly more memory cells 1125 (e.g., tens, hundreds, or thousands of memory cells) per row or per column.

Each memory cell 1125 can include a single transistor 1127 and a single capacitor 1129, which is commonly referred to as a 1T1C (one-transistor—one capacitor cell). One plate of capacitor 1129, which can be termed the “node plate,” is connected to the drain terminal of transistor 1127, whereas the other plate of the capacitor 1129 is connected to ground 1124. Each capacitor 1129 within the array of 1T1C cells 1125 typically serves to store one bit of data, and the respective transistor 1127 serves as an access device to write to or read from storage capacitor 1129.

The transistor gate terminals within each row of rows 1154-1, 1154-2, 1154-3, and 1154-4 are portions of respective access lines 1130-1, 1130-2, 1130-3, and 1130-4 (alternatively referred to as “word lines”), and the transistor source terminals within each of columns 1156-1, 1156-2, 1156-3, and 1156-4 are electrically connected to respective digit lines 1110-1, 1110-2, 1110-3, and 1110-4 (alternatively referred to as “bit lines”). A row decoder 1132 can selectively drive the individual access lines 1130-1, 1130-2, 1130-3, and 1130-4, responsive to row address signals 1131 input to row decoder 1132. Driving a given access line at a high voltage causes the access transistors within the respective row to conduct, thereby connecting the storage capacitors within the row to the respective data lines, such that charge can be transferred between the data lines and the storage capacitors for read or write operations. Both read and write operations can be performed via sense amplifier circuitry 1140, which can transfer bit values between the memory cells 1125 of the selected row of the rows 1154-1, 1154-2, 1154-3, and 1154-4 and input/output buffers 1146 (for write/read operations) or external input/output data buses 1148. Sense amplifier circuitry 1140 can include one or more FinFETs structured with gate wrapping around fins to maintain good channel control and structured with planar source and drain.

A column decoder 1142 responsive to column address signals 1141 can select which of the memory cells 1125 within the selected row is read out or written to. Alternatively, for read operations, the storage capacitors 1129 within the selected row can be read out simultaneously and latched, and the column decoder 1142 can then select which latch bits to connect to the output data bus 1148. Since read-out of the storage capacitors destroys the stored information, the read operation is accompanied by a simultaneous rewrite of the capacitor charge. Further, in between read/write operations, the capacitor charge is repeatedly refreshed to prevent data loss. Details of read/rewrite, write, and refresh operations are well-known to those of ordinary skill in the art.

DRAM device 1100 may be implemented as an integrated circuit within a package that includes pins for receiving supply voltages (e.g., to provide the source and gate voltages for the transistors 1127) and signals (including data, address, and control signals). FIG. 11 depicts DRAM device 1100 in simplified form to illustrate basic structural components, omitting many details of the memory cells 1125 and associated access lines 1130-1, 1130-2, 1130-3, and 1130-4 and digit lines 1110-1, 1110-2, 1110-3, and 1110-4 as well as the peripheral circuitry. For example, in addition to the row decoder 1132 and column decoder 1142, sense amplifier circuitry 1140, and buffers 1146, DRAM device 1100 can include further peripheral circuitry, such as a memory control unit that controls the memory operations based on control signals (provided, e.g., by an external processor), additional input/output circuitry, etc. Details of such peripheral circuitry are generally known to those of ordinary skill in the art and not further discussed herein.

In two-dimensional (2D) DRAM arrays, the rows 1154-1, 1154-2, 1154-3, and 1154-4 and columns 1156-1, 1156-2, 1156-3, and 1156-4 of memory cells 1125 are arranged along a single horizontal plane (i.e., a plane parallel to the layers) of the semiconductor substrate, e.g., in a rectangular lattice with mutually perpendicular horizontal access lines 1130-1, 1130-2, 1130-3, and 1130-4 and digit lines 1110-1, 1110-2, 1110-3, and 1110-4. In 3D DRAM arrays, the memory cells 1125 are arranged in a 3D lattice that encompasses multiple vertically stacked horizontal planes corresponding to multiple device tiers of a multi-tier substrate assembly, with each device tier including multiple parallel rows of cells 1125 whose transistor gate terminals are connected by horizontal access lines such as access lines 1130-1, 1130-2, 1130-3, and 1130-4. (A “device tier,” as used herein, can include multiple layers (or levels) of materials, but forms the components of memory devices of a single horizontal tier of memory cells.) Digit lines 1110-1, 1110-2, 1110-3, and 1110-4 extend vertically through all or at least a vertical portion of the multi-tier structure, and each of the digit lines 1110-1, 1110-2, 1110-3, and 1110-4 connects to the transistor source terminals of respective vertical columns 1156-1, 1156-2, 1156-3, and 1156-4 of associated memory cells 1125 at the multiple device tiers. This 3D configuration of memory cells enables further increases in bit density compared with 2D arrays.

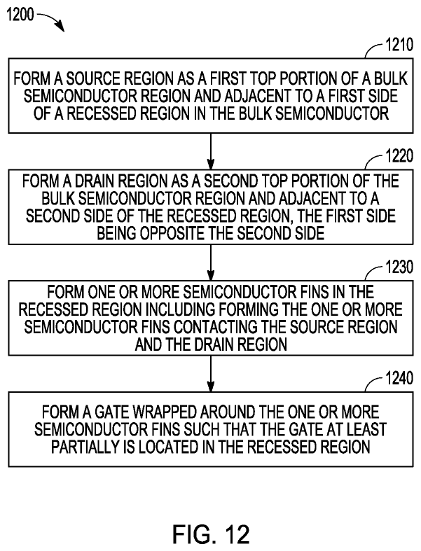

FIG. 12 is a flow diagram of an embodiment of example features of a method 1200 of forming a device including a FinFET. At 1210, a source region is formed as a first top portion of a bulk semiconductor region. The source region is formed adjacent to a first side of a recessed region in the bulk semiconductor. At 1220, a drain region is formed as a second top portion of the bulk semiconductor region. The drain region is formed adjacent to a second side of the recessed region, where the first side is opposite the second side. At 1230, one or more semiconductor fins are formed in the recessed region including forming the one or more semiconductor fins contacting the source region and the drain region. At 1240, a gate is formed wrapped around the one or more semiconductor fins such that the gate at least partially is located in the recessed region.

Variations of method 1200 or methods similar to method 1200 can include a number of different embodiments that can be combined depending on the application of such methods and/or the architecture of devices for which such methods are implemented. Such methods can include forming the source region and the drain region by epitaxially forming p+ silicon germanium. Such methods can include forming the source region and the drain region by forming the source region and the drain region with p+ implants.

Variations of method 1200 or methods similar to method 1200 can include forming the gate as a polysilicon gate on a gate nitride, which can be used in a replacement procedure. The polysilicon gate and the gate nitride can be replaced with a metal gate on a gate dielectric including a dielectric having a dielectric constant greater than 3.9. Contacts are formed to the metal gate, the drain region, and the source region. Forming the metal gate can include forming a work function metal as an outer boundary of the gate metal and filling a region defined by the outer boundary with a primary metal for the metal gate. The work function metal can include TiN or TaN; the primary metal can include W; and the gate dielectric can include HfOₓ on SiOₓ.

In various embodiments, a fin field-effect transistor can comprise a bulk semiconductor region having a recessed region, where the bulk semiconductor region is located on a substrate. A source region can be structured as a first top portion of the bulk semiconductor region, where the source region is located adjacent to a first side of the recessed region. A drain region can be structured as a second top portion of the bulk semiconductor region, where the drain region is located adjacent to a second side of the recessed region, with the first side being opposite the second side. One or more semiconductor fins can be structured in the recessed region, where the one or more semiconductor fins contact the source region and the drain region. The one or more semiconductor fins can be composed of material of the bulk semiconductor. A gate is wrapped around the one or more semiconductor fins. The gate can be positioned at least partially in the recessed region. The gate can be separated from each of the one or more semiconductor fins by a gate dielectric.

Variations of such a fin field-effect transistor and its features, as taught herein, can include a number of different embodiments and features that can be combined depending on the application of such fin field-effect transistors, the format of such fin field-effect transistors, and/or the architecture in which such fin field-effect transistors are implemented. Features of such fin field-effect transistors can include the bulk semiconductor and the one or more semiconductor fins including silicon, the gate including a metal structure, and the gate dielectric including a dielectric having a dielectric constant greater than 3.9. The dielectric can be located on a SiOₓ between the source region and the drain region.

Variations of such a fin field-effect transistor and its features can include the fin field-effect transistor being a p-channel fin field-effect transistor with the source region and the drain region including epitaxial silicon germanium. The fin field-effect transistor can be a p-channel fin field-effect transistor with the source region and the drain having p+ implants. The fin field-effect transistor can be a n-channel fin field-effect transistor with the source region and the drain region having n+ implants.

In various embodiments, a memory device can comprise an array of memory cells and circuits for controlling operation of the array, where the circuits include a fin field-effect transistor. The fin field-effect transistor can include a source region structured as a first top portion of a bulk semiconductor region, where the source region is located adjacent to a first side of a recessed region in the bulk semiconductor and a drain region structured as a second top portion of the bulk semiconductor region, where the drain region is located adjacent to a second side of the recessed region. The first side is opposite the second side. One or more semiconductor fins can be structured in the recessed region, where the one or more semiconductor fins contact the source region and the drain region. The fin field-effect transistor can include a gate wrapped around the one or more semiconductor fins, where the gate is at least partially in the recessed region.

Variations of such a memory device and its features, as taught herein, can include a number of different embodiments and features that can be combined depending on the application of such memory devices, the format of such memory devices, and/or the architecture in which such memory devices are implemented. Features of such memory devices can include the circuits located in a periphery region adjacent the memory array. The circuits can be located in a region under the memory array.

Variations of such a memory device and its features can include the fin field-effect transistor being a p-channel fin field-effect transistor with the source region and the drain region including epitaxial silicon germanium. The fin field-effect transistor memory device can be a p-channel fin field-effect transistor with the source region and the drain include p+ implants. The fin field-effect transistor memory device can be a n-channel fin field-effect transistor with the source region and the drain region including n+ implants.

Electronic devices, such as mobile electronic devices (e.g., smart phones, tablets, etc.), electronic devices for use in automotive applications (e.g., automotive sensors, control units, driver-assistance systems, passenger safety or comfort systems, etc.), and internet-connected appliances or devices (e.g., internet-of-things (IoT) devices, etc.), have varying storage needs depending on, among other things, the type of electronic device, use environment, performance expectations, etc. Electronic devices can be broken down into several main components: a processor (e.g., a central processing unit (CPU) or other main processor); memory (e.g., one or more volatile or non-volatile RAM memory device, such as DRAM, mobile or low-power double-data-rate synchronous DRAM (DDR SDRAM), etc.); and a storage device (e.g., non-volatile memory (NVM) device, such as flash memory, ROM, a solid-state drive (SSD), a MultiMediaCard (MMC), or other memory card structure or assembly, etc.). In certain examples, electronic devices can include a user interface (e.g., a display, touch-screen, keyboard, one or more buttons, etc.), a graphics processing unit (GPU), a power management circuit, a baseband processor or one or more transceiver circuits, etc. As used herein, “processor device” means any type of computational circuit such as, but not limited to, a microprocessor, a microcontroller, a graphics processor, a digital signal processor (DSP), or any other type of processor or processing circuit, including a group of processors or multi-core devices.

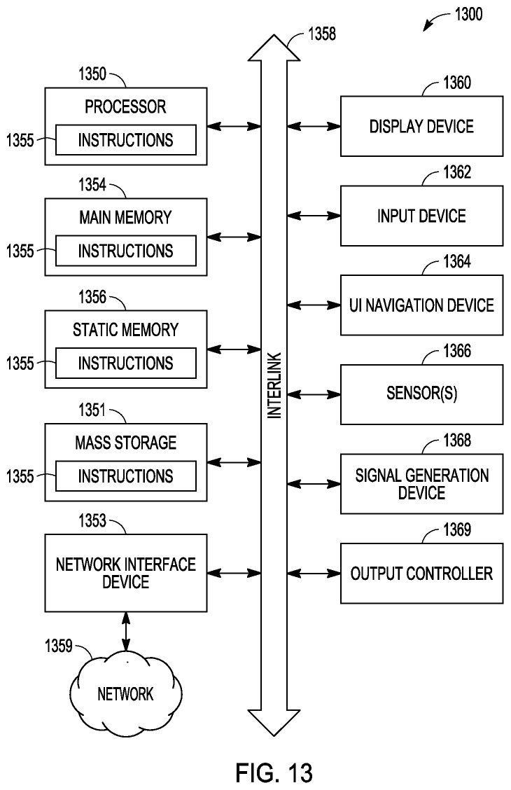

FIG. 13 illustrates a block diagram of an example machine 1300 having one or more embodiments of FinFETs discussed herein. In alternative embodiments, machine 1300 can operate as a standalone device or can be connected (e.g., networked) to other machines. In a networked deployment, machine 1300 can operate in the capacity of a server machine, a client machine, or both in server-client network environments. In an example, machine 1300 can act as a peer machine in peer-to-peer (P2P) (or other distributed) network environment. Machine 1300 can be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies such as cloud computing, software as a service (SaaS), other computer cluster configurations.

Examples, as described herein, can include, or can operate by, logic, components, devices, packages, or mechanisms. Circuitry is a collection (e.g., set) of circuits implemented in tangible entities that include hardware (e.g., simple circuits, gates, logic, etc.). Circuitry membership can be flexible over time and underlying hardware variability. Circuitries include members that can, alone or in combination, perform specific tasks when operating. In an example, hardware of the circuitry can be immutably designed to carry out a specific operation (e.g., hardwired). In an example, the hardware of the circuitry can include variably connected physical components (e.g., execution units, transistors, simple circuits, etc.) including a computer readable medium physically modified (e.g., magnetically, electrically, moveable placement of invariant massed particles, etc.) to encode instructions of the specific operation. The instructions enable participating hardware (e.g., the execution units or a loading mechanism) to create members of the circuitry in hardware via the variable connections to carry out portions of the specific tasks when in operation. Accordingly, the computer readable medium is communicatively coupled to the other components of the circuitry when the device is operating. In an example, any of the physical components can be used in more than one member of more than one circuitry.

The machine 1300 can include a hardware processor 1350 (e.g., a CPU, a GPU, a hardware processor core, or any combination thereof), a main memory 1354, and a static memory 1356, some or all of which can communicate with each other via an interlink 1358 (e.g., bus). Machine 1300 can further include a display device 1360, an input device 1362, which can be an alphanumeric input device (e.g., a keyboard), and a user interface (UI) navigation device 1364 (e.g., a mouse). In an example, display device 1360, input device 1362, and UI navigation device 1364 can be a touch screen display. Machine 1300 can additionally include a mass storage device (e.g., drive unit) 1351, a network interface device 1353, a signal generation device 1368, and one or more sensors 1366, such as a global positioning system (GPS) sensor, compass, accelerometer, or other sensor. Machine 1300 can include an output controller 1369, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

Machine 1300 can include one or more machine-readable media on which is stored one or more sets of data structures or instructions 1355 (e.g., software, microcode, or other type of instructions) embodying or utilized by machine 1300 to perform any one or more of the techniques or functions for which machine 1300 is designed. The instructions 1355 can reside, completely or at least partially, within main memory 1354, within static memory 1356, or within hardware processor 1350 during execution thereof by machine 1300. In an example, one or any combination of hardware processor 1350, main memory 1354, static memory 1356, or mass storage device 1351 can constitute the machine-readable media on which is stored one or more sets of data structures or instructions.

While an example machine-readable medium is illustrated as a single medium, the term “machine-readable medium” can include a single medium or multiple media (e.g., a centralized or distributed database, or associated caches and servers) configured to store instructions 1355 or data. The term “machine-readable medium” can include any medium that is capable of storing instructions for execution by machine 1300 and that cause machine 1300 to perform any one or more of the techniques to which machine 1300 is designed, or that is capable of storing data structures used by or associated with such instructions. Non-limiting machine-readable medium examples can include solid-state memories, optical media, and magnetic media. Specific examples of non-transitory machine-readable media can include: non-volatile memory, such as semiconductor memory devices (e.g., EPROM, EEPROM) and flash memory devices; magnetic disks, such as internal hard disks and removable disks; magneto-optical disks; and compact disc-ROM (CD-ROM) and digital versatile disc-read only memory (DVD-ROM) disks.

Instructions 1355 (e.g., software, programs, an operating system (OS), etc.) or other data stored on mass storage device 1351 can be accessed by main memory 1354 for use by hardware processor 1350. Main memory 1354 (e.g., DRAM) is typically fast, but volatile, and thus a different type of storage than mass storage device 1351 (e.g., an SSD), which is suitable for long-term storage, including while in an “off” condition. Instructions 1355 or data in use by a user or machine 1300 are typically loaded in main memory 1354 for use by hardware processor 1350. When main memory 1354 is full, virtual space from mass storage device 1351 can be allocated to supplement main memory 1354; however, because mass storage device 1351 is typically slower than main memory 1354, and write speeds are typically at least twice as slow as read speeds, use of virtual memory can greatly reduce user experience due to storage device latency (in contrast to main memory 1354, e.g., DRAM). Further, use of mass storage device 1351 for virtual memory can greatly reduce the usable lifespan of mass storage device 1351.

Storage devices optimized for mobile electronic devices, or mobile storage, traditionally include MMC solid-state storage devices (e.g., micro Secure Digital (microSD™) cards, etc.). MMC devices include a number of parallel interfaces (e.g., an 8-bit parallel interface) with a host device and are often removable and separate components from the host device. In contrast, embedded MMC (eMMC™) devices are attached to a circuit board and considered a component of the host device, with read speeds that rival Serial Advanced Technology Attachment (SATA)-based SSD devices. However, demand for mobile device performance continues to increase, such as to fully enable virtual or augmented-reality devices, utilize increasing networks speeds, etc. In response to this demand, storage devices have shifted from parallel to serial communication interfaces. Universal Flash Storage (UFS) devices, including controllers and firmware, communicate with a host device using a low-voltage differential signaling (LVDS) serial interface with dedicated read/write paths, further advancing greater read/write speeds.

Instructions 1355 can further be transmitted or received over a network 1359 using a transmission medium via signal generation device 1368 or network interface device 1353 utilizing any one of a number of transfer protocols (e.g., frame relay, Internet protocol (IP), transmission control protocol (TCP), user datagram protocol (UDP), hypertext transfer protocol (HTTP), etc.). Example communication networks can include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, signal generation device 1368 or network interface device 1353 can include one or more physical jacks (e.g., Ethernet, coaxial, or phone jacks) or one or more antennas to connect to network 1359. In an example, signal generation device 1368 or network interface device 1353 can include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible medium that is capable of carrying instructions to and for execution by machine 1300 or data to or from machine 1300, and can include instrumentalities to propagate digital or analog communications signals to facilitate communication of such instructions, which instructions may be implemented by software or data.

The following are example embodiments of devices and methods, in accordance with the teachings herein.

An example fin field-effect transistor 1 can comprise: a bulk semiconductor region having a recessed region, the bulk semiconductor region located on a substrate; a source region structured as a first top portion of the bulk semiconductor region, the source region located adjacent to a first side of the recessed region; a drain region structured as a second top portion of the bulk semiconductor region, the drain region located adjacent to a second side of the recessed region, the first side being opposite the second side; one or more semiconductor fins in the recessed region, the one or more semiconductor fins contacting the source region and the drain region; a gate wrapped around the one or more semiconductor fins, the gate at least partially in the recessed region.

An example fin field-effect transistor 2 can include features of example fin field-effect transistor 1 and can include the one or more semiconductor fins being composed of material of the bulk semiconductor region.

An example fin field-effect transistor 3 can include features of any features of the preceding example fin field-effect transistors and can include the gate being separated from each of the one or more semiconductor fins by a gate dielectric having multiple dielectric regions.

An example fin field-effect transistor 4 can include features of example fin field-effect transistor 3 and any of the preceding example fin field-effect transistors and can include the bulk semiconductor region and the one or more semiconductor fins including silicon, the gate to include a metal structure, and the gate dielectric to include a dielectric having a dielectric constant greater than 3.9.

An example fin field-effect transistor 5 can include features of example fin field-effect transistor 4 and any of the preceding example fin field-effect transistors and can include the dielectric being located on a silicon oxide between the source region and the drain region.

An example fin field-effect transistor 6 can include features of any of the preceding example fin field-effect transistors and can include the fin field-effect transistor being a p-channel fin field-effect transistor with the source region and the drain region including epitaxial silicon germanium.

An example fin field-effect transistor 7 can include features of any of the preceding example fin field-effect transistors and can include the fin field-effect transistor being a p-channel fin field-effect transistor with the source region and the drain region including p+ implants.

An example fin field-effect transistor 8 can include features of any of the preceding example fin field-effect transistors and can include the fin field-effect transistor being a n-channel fin field-effect transistor with the source region and the drain region including n+ implants.

In an example fin field-effect transistor 9, any of the fin field-effect transistors of example fin field-effect transistors 1 to 8 may include fin field-effect transistors incorporated into an electronic memory apparatus further comprising a host processor and a communication bus extending between the host processor and the fin field-effect transistor.

In an example fin field-effect transistor 10, any of the fin field-effect transistors of example fin field-effect transistors 1 to 9 may be modified to include any structure presented in another of example fin field-effect transistor 1 to 9.

In an example fin field-effect transistor 11, any apparatus associated with the fin field-effect transistors of example fin field-effect transistors 1 to 10 may further include a machine-readable storage device configured to store instructions as a physical state, wherein the instructions may be used to perform one or more operations of the apparatus.

In an example fin field-effect transistor 12, any of the fin field-effect transistors of example fin field-effect transistors 1 to 11 may be operated in accordance with any of the below example methods 1 to 10.

An example memory device 1 can comprise: an array of memory cells; and circuits for controlling operation of the array, the circuits including a fin field-effect transistor, the fin field-effect transistor including: a source region structured as a first top portion of a bulk semiconductor region, the source region located adjacent to a first side of a recessed region in the bulk semiconductor; a drain region structured as a second top portion of the bulk semiconductor region, the drain region located adjacent to a second side of the recessed region, the first side being opposite the second side; one or more semiconductor fins in the recessed region, the one or more semiconductor fins contacting the source region and the drain region; a gate wrapped around the one or more semiconductor fins, the gate at least partially in the recessed region.

An example memory device 2 can include features of example memory device 1 and can include the circuits being located in a periphery region adjacent the memory array.

An example memory device 3 can include features of any features of the preceding example memory devices and can include the circuits being located in a region under the memory array.

An example memory device 4 can include features of any of the preceding example memory devices and can include the fin field-effect transistor being a p-channel fin field-effect transistor with the source region and the drain region including epitaxial silicon germanium.

An example memory device 5 can include features of any features of the preceding example memory devices and can include the fin field-effect transistor being a p-channel fin field-effect transistor with the source region and the drain region including p+ implants.

An example memory device 6 can include features of any features of the preceding example memory devices and can include the fin field-effect transistor being a n-channel fin field-effect transistor with the source region and the drain region including n+ implants.

In an example memory device 7, any of the memory devices of example memory devices 1 to 6 may include memory devices incorporated into an electronic memory apparatus further comprising a host processor and a communication bus extending between the host processor and the memory device.

In an example memory device 8, any of the memory devices of example memory devices 1 to 7 may be modified to include any structure presented in another of example memory device 1 to 7.

In an example memory device 9, any apparatus associated with the memory devices of example memory devices 1 to 8 may further include a machine-readable storage device configured to store instructions as a physical state, wherein the instructions may be used to perform one or more operations of the apparatus.

In an example memory device 10, any of the memory devices of example memory devices 1 to 9 may be formed in accordance with any of the methods of the below example methods 1 to 10.

An example method 1 can comprise: forming a source region as a first top portion of a bulk semiconductor region and adjacent to a first side of a recessed region in the bulk semiconductor region; forming a drain region as a second top portion of the bulk semiconductor region and adjacent to a second side of the recessed region, the first side being opposite the second side; forming one or more semiconductor fins in the recessed region including forming the one or more semiconductor fins contacting the source region and the drain region; and forming a gate wrapped around the one or more semiconductor fins such that the gate at least partially is located in the recessed region.

An example method 2 can include features of example method 1 and can forming the source region and the drain region to include epitaxially forming p+ silicon germanium.

An example method 3 can include features of any of the preceding example methods and can include forming the source region and the drain region to include forming the source region and the drain region with p+ implants.

An example method 4 can include features of any of the preceding example methods and can include forming the gate as a polysilicon gate on a gate nitride; replacing the polysilicon gate and the gate nitride with a metal gate on a gate dielectric including a dielectric having a dielectric constant greater than 3.9; and forming a gate contact to the metal gate, a drain contact to the drain region, and a source contact to the source region.

An example method 5 can include features of example method 4 and any of the preceding example methods and can include forming the metal gate to include forming a work function metal as an outer boundary of the gate metal and filling a region defined by the outer boundary with a primary metal for the metal gate.

An example method 6 can include features of example method 5 and any of the preceding example methods and can include the work function metal to include titanium nitride or tantalum nitride, the primary metal includes tungsten, and the gate dielectric includes hafnium oxide on silicon oxide.

In an example method 7, any of the example methods 1 to 6 may be performed in forming an electronic memory apparatus further comprising a host processor and a communication bus extending between the host processor and the memory device.

In an example method 8, any of the example methods 1 to 7 may be modified to include operations set forth in any other of example methods 1 to 7.

In an example method 9, any of the example methods 1 to 8 may be implemented at least in part through use of instructions stored as a physical state in one or more machine-readable storage devices.

An example method 10 can include features of any of the preceding example methods 1 to 9 and can include performing functions associated with any features of example memory devices 1 to 10 and example fin field-effect transistor 1 to 12.

An example machine-readable storage device 1 storing instructions, that when executed by one or more processors, cause a machine to perform operations, can comprise instructions to perform functions associated with any features of example memory devices 1 to 10 and example fin field-effect transistor 1 to 12 or perform methods associated with any features of example methods 1 to 10.

Although specific embodiments have been illustrated and described herein, it will be appreciated by those of ordinary skill in the art that any arrangement that is calculated to achieve the same purpose may be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A fin field-effect transistor comprising:
a bulk semiconductor region having a recessed region, the bulk semiconductor region located on a substrate;
a source region structured as a first top portion of the bulk semiconductor region, the source region located adjacent to a first side of the recessed region;
a drain region structured as a second top portion of the bulk semiconductor region, the drain region located adjacent to a second side of the recessed region, the first side being opposite the second side;
one or more semiconductor fins in the recessed region, the one or more semiconductor fins contacting the source region and the drain region; and
a gate wrapped around the one or more semiconductor fins, the gate at least partially in the recessed region.

2. The fin field-effect transistor of claim 1, wherein the one or more semiconductor fins are composed of material of the bulk semiconductor region.

3. The fin field-effect transistor of claim 1, wherein the gate is separated from each of the one or more semiconductor fins by a gate dielectric having multiple dielectric regions.

4. The fin field-effect transistor of claim 3, wherein the bulk semiconductor region and the one or more semiconductor fins include silicon, the gate includes a metal structure, and the gate dielectric includes a dielectric having a dielectric constant greater than 3.9.

5. The fin field-effect transistor of claim 4, wherein the dielectric is located on a silicon oxide between the source region and the drain region.

6. The fin field-effect transistor of claim 1, wherein the fin field-effect transistor is a p-channel fin field-effect transistor with the source region and the drain region including epitaxial silicon germanium.

7. The fin field-effect transistor of claim 1, wherein the fin field-effect transistor is a p-channel fin field-effect transistor with the source region and the drain region including p+ implants.

8. The fin field-effect transistor of claim 1, wherein the fin field-effect transistor is a n-channel fin field-effect transistor with the source region and the drain region including n+ implants.

9. A memory device comprising:
an array of memory cells; and
circuits for controlling operation of the array, the circuits including a fin field-effect transistor, the fin field-effect transistor including:
a source region structured as a first top portion of a bulk semiconductor region, the source region located adjacent to a first side of a recessed region in the bulk semiconductor;
a drain region structured as a second top portion of the bulk semiconductor region, the drain region located adjacent to a second side of the recessed region, the first side being opposite the second side;
one or more semiconductor fins in the recessed region, the one or more semiconductor fins contacting the source region and the drain region; and
a gate wrapped around the one or more semiconductor fins, the gate at least partially in the recessed region.

10. The memory device of claim 9, wherein the circuits are located in a periphery region adjacent the memory array.

11. The memory device of claim 9, wherein the circuits are located in a region under the memory array.

12. The memory device of claim 9, wherein the fin field-effect transistor is a p-channel fin field-effect transistor with the source region and the drain region including epitaxial silicon germanium.

13. The memory device of claim 9, wherein the fin field-effect transistor is a p-channel fin field-effect transistor with the source region and the drain region including p+ implants.

14. The memory device of claim 9, wherein the fin field-effect transistor is a n-channel fin field-effect transistor with the source region and the drain region including n+ implants.

15. A method comprising:
forming a source region as a first top portion of a bulk semiconductor region and adjacent to a first side of a recessed region in the bulk semiconductor region;
forming a drain region as a second top portion of the bulk semiconductor region and adjacent to a second side of the recessed region, the first side being opposite the second side;
forming one or more semiconductor fins in the recessed region including forming the one or more semiconductor fins contacting the source region and the drain region; and
forming a gate wrapped around the one or more semiconductor fins such that the gate at least partially is located in the recessed region.

16. The method of claim 15, wherein forming the source region and the drain region includes epitaxially forming p+ silicon germanium.

17. The method of claim 15, wherein forming the source region and the drain region includes forming the source region and the drain region with p+ implants.

18. The method of claim 15, wherein the method includes:
forming the gate as a polysilicon gate on a gate nitride;
replacing the polysilicon gate and the gate nitride with a metal gate on a gate dielectric including a dielectric having a dielectric constant greater than 3.9; and
forming a gate contact to the metal gate, a drain contact to the drain region, and a source contact to the source region.

19. The method of claim 18, wherein forming the metal gate includes forming a work function metal as an outer boundary of the gate metal and filling a region defined by the outer boundary with a primary metal for the metal gate.

20. The method of claim 19, wherein the work function metal incudes titanium nitride or tantalum nitride, the primary metal includes tungsten, and the gate dielectric includes hafnium oxide on silicon oxide.
